(19) United States
(12) Patent Application Publication
(10) Pub. No.: US 2023/0299223 A1
(43) Pub. Date: Sep. 21, 2023

(54) PHOTODIODE STRUCTURES

(71) Applicant: Sensors Unlimited, Inc., Princeton, NJ (US)

(72) Inventors: John Liobe, New York, NY (US); Krishna Linga, Plainsboro, NJ (US); Wei Huang, Plainsborough, NJ (US)

(73) Assignee: Sensors Unlimited, Inc., Princeton, NJ (US)

(21) Appl. No.: 17/696,342

(22) Filed: Mar. 16, 2022

Related U.S. Application Data
(60) Provisional application No. 63/320,678, filed on Mar. 16, 2022.

(51) Int. Cl. H01L 31/107; H01L 31/0352; H01L 31/0304

(52) U.S. Cl. CPC H01L 31/1075; H01L 31/035281; H01L 31/03046

(57) ABSTRACT

In accordance with at least one aspect of this disclosure, a photodiode structure can include a charge layer comprised of undoped InP, and a detector active area forming a junction with the charge layer and having edges configured to prevent edge breakdown. The location of the junction can be controlled through a diffusion of the detector active area or through an epitaxially grown doped region, for example. The photodiode structure can also include a charge control layer comprised of doped InP. The charge control layer can include a thickness and carrier concentration configured to achieve a predetermined gain, high speed, low dark current, and low break down voltage.

### CROSS-REFERENCE TO RELATED APPLICATIONS

This application claims priority to and the benefit of U.S. Provisional Patent Application No. 63/320,678, filed Mar. 16, 2022, the entire content of which is incorporated herein by reference.

### FIELD

This disclosure relates to photodiode structures.

### BACKGROUND

InGaAs/InP based separate absorption, grading, charge, and multiplication (SAGCM) photodetectors are generally have breakdown voltages in the order of 60-70V. Higher break down voltage leads to higher operating voltage and hence leads to higher dark current. Higher breakdown voltage also forces the need for higher supply voltage in the system leading to higher power dissipation.

A primary challenge to achieving high sensitivity avalanche photo diodes (APDs), e.g., at 1550 nm wavelength, is that the small band-gap materials such as InGaAs necessary to detect low-energy photons exhibit higher dark counts and higher multiplication noise. The material properties such as bandgap, intrinsic carrier concentration, and ionization coefficients, for example, are not available in a single semiconductor material to produce an avalanche photodiode (APD) that has high quantum efficiency, e.g., from 1000 nm to 1700 nm wavelengths, while also having low noise and high enough gain.

An established approach in APD design to circumvent the limitations of a single material is to use separate absorption and multiplication (SAM) regions. However, the combination of non-ideal carrier ionization properties in III-V materials, for example, and the challenge of lattice matching Si to a narrow bandgap material has prevented the creation of an ideal SAM-APD with both 1550 nm sensitivity and multiplication performance similar to silicon APDs.

In order to overcome this challenge, a III-V material must be engineered to have improved multiplication properties or a novel technique to integrate a narrow bandgap material with silicon must be developed. One such approach is the design of a Separate Absorption Charge and Multiplication (SACM) APD by engineering the multiplication region. However, the traditional APD's with a InP/InGaAs/InGaAsP material systems typically have breakdown voltages as high as 80V with significant breakdown voltage variation even for small format APD pixel arrays.

Such conventional methods and systems have generally been considered satisfactory for their intended purpose. However, there is still a need in the art for improved avalanche photodiode structures. The present disclosure provides a solution for this need.

### SUMMARY

A photodiode structure can include a substrate layer comprising strongly doped InP, a buffer layer disposed on the substrate layer and comprising InP, wherein the buffer layer can be either undoped or doped the same type as the substrate, an absorption layer disposed on the buffer layer and comprising InGaAs, wherein the absorption layer can be undoped or mildly doped the same type as the buffer layer, and a plurality of transition layers disposed on the absorption layer. The plurality of transition layers can include quaternary InGaAsP and can transition from a first transition layer in contact with the absorption layer having a higher concentration of GaAs to a last transition layer having a higher concentration of P. The structure can include a charge control layer disposed on the last transition layer and comprising doped InP, wherein the charge control layer can be doped the same type as the substrate layer, a charge layer disposed on the charge control layer and comprised of InP, wherein the charge layer can be undoped or lightly doped the same type as the substrate layer, and a cap layer disposed on the charge layer and comprised of InP, wherein the cap layer can be undoped or mildly doped the same type as the substrate layer.

The structure can include a detector active area disposed within the charge layer and the cap layer. The detector active area can include a strongly doped material, wherein the detector active area can be doped the opposite type as the substrate. The detector active area can extend through the cap layer and into the charge layer to a depth thereby defining a multiplication region of the charge layer between the detector active area and the charge control layer. The detector active area can include a shape without any sharp edges (e.g., rounded) within the charge layer and the cap layer to prevent electric field concentration.

The structure can also include an anode disposed on the detector active area. The structure can also include a cathode having an optical opening. The cathode can be disposed on the substrate layer on an opposite side thereof as the buffer layer.

The structure can also include a cathode dielectric disposed in the optical opening. The structure can also include an anode dielectric disposed between the anode and the cap layer.

The anode dielectric can extend over a portion of the detector active area. Each layer can include a relative thickness, e.g., as shown in FIG. 1 and/or as otherwise disclosed herein.

In certain embodiments, the detector active area has a semi ellipsoidal shape. The detector active area can include a hemispherical shape, for example. Any other shape is contemplated herein where there is no concentrated electric field around the perimeter of the detector active area.

In certain embodiments, the photodiode structure forms an avalanche photodiode. Any other photodiode and operating wavelengths thereof are contemplated herein.

In accordance with at least one aspect of this disclosure, a photodetector can include a plurality of pixels. Each pixel can include a photodiode structure as disclosed herein, e.g., as described above. In certain embodiments, the photodetector is configured to sense wavelengths between about 1000 nm to about 1700 nm.

In accordance with at least one aspect of this disclosure, a photodiode structure can include a charge layer comprised of undoped InP, and a detector active area forming a junction with the charge layer and having edges configured to prevent edge breakdown. The location of the junction can be controlled through a diffusion of the detector active area or through an epitaxially grown doped region, for example. The photodiode structure can also include a charge control layer comprised of doped InP. The charge control layer can include a thickness and carrier concentration configured to achieve a predetermined gain, high speed, low dark current, and low break down voltage.

In accordance with at least one aspect of this disclosure, a method can include forming a smooth detector active area to form a strongly doped junction for a photodiode. The detector active area can be formed in a photodetector structure that is configured to sense one or more wavelengths between about 1000 nm to about 1700 nm, and/or one or more wavelengths between about 400 nm to about 2600 nm. The method can include any other suitable method(s) and/or portion(s) thereof.

These and other features of the embodiments of the subject disclosure will become more readily apparent to those skilled in the art from the following detailed description taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a cross-sectional view of an embodiment of a photodiode structure in accordance with this disclosure;

FIG. 1A is a cross-sectional view of an embodiment of a photodiode structure in accordance with this disclosure;

FIG. 1B is a cross-sectional view of an embodiment of a photodiode structure in accordance with this disclosure; and

FIG. 2 is a chart showing reverse bias voltage vs current and gain, showing dark current, light current, and gain.

### DETAILED DESCRIPTION

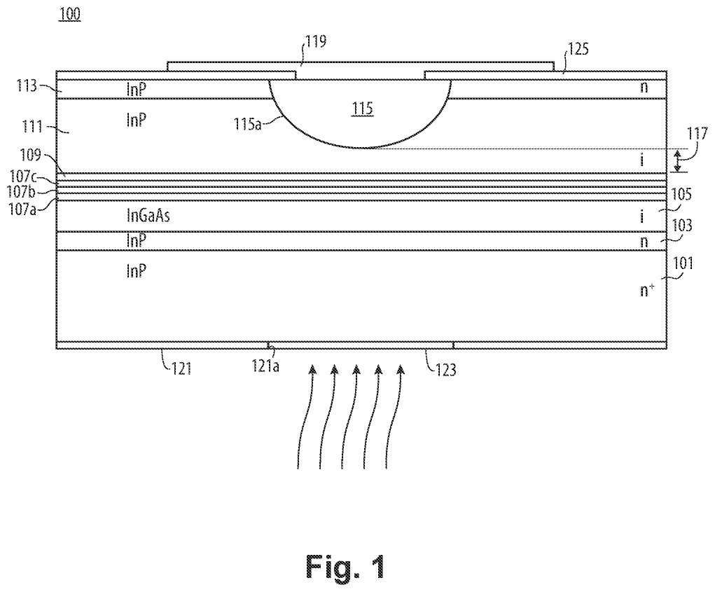

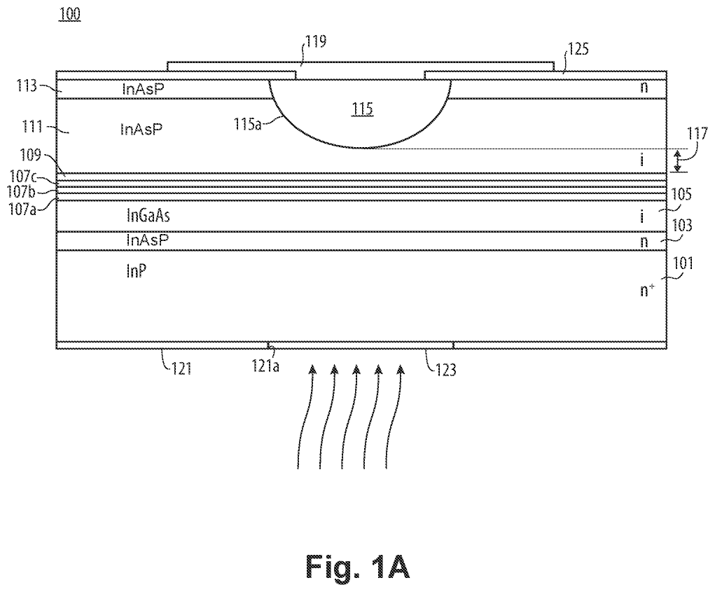

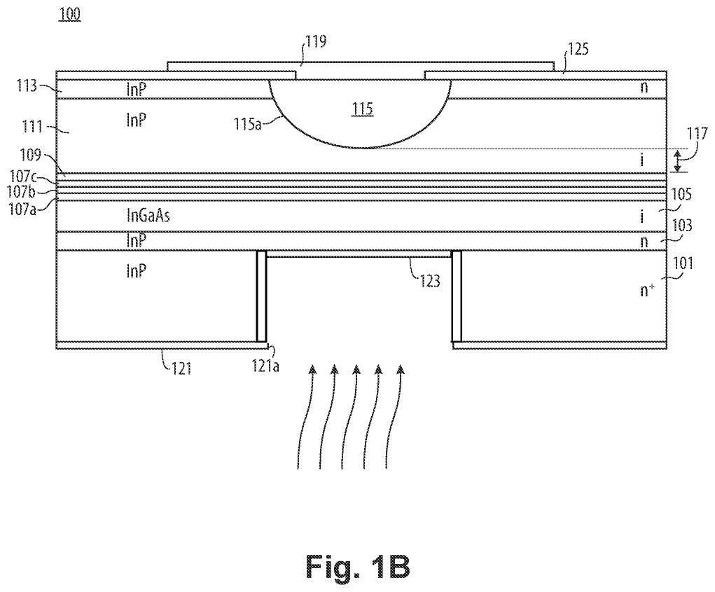

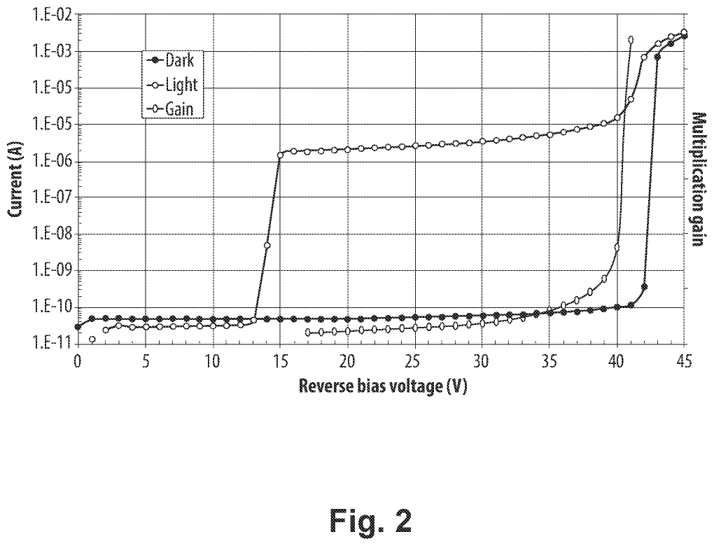

Reference will now be made to the drawings wherein like reference numerals identify similar structural features or aspects of the subject disclosure. For purposes of explanation and illustration, and not limitation, an illustrative view of an embodiment of a photodiode structure in accordance with the disclosure is shown in FIG. 1 and is designated generally by reference character 100. Other embodiments and/or aspects of this disclosure are shown in FIGS. 1A, 1B, and 2.

In accordance with at least one aspect of this disclosure, referring to FIG. 1, a photodiode structure 100 can include a substrate layer 101. The substrate layer 101 can be made of strongly doped InP (e.g., n-doped as shown or p-doped), for example. One having ordinary skill in the art understands the terms “strongly doped”, “mildly doped”, “lightly doped”, “doped”, and “undoped” as used herein.

The structure 100 can include a buffer layer 103 disposed on the substrate layer 103. The buffer layer 103 can be either undoped or doped the same type as the substrate 101. The buffer layer 103 can be made of doped InP (e.g., n-doped as shown), for example (e.g., less doped than the substrate layer).

The structure 100 can include an absorption layer 105 disposed on the buffer layer 103. The absorption layer 105 can be undoped or mildly doped the same type as the buffer layer 103 (e.g., n-doped as shown). In certain embodiments, the absorption layer 105 can be made of undoped InGaAs, for example.

The structure 100 can also include a plurality transition layers 107a, b, c disposed on the absorption layer 105. The plurality of transition layers 107a, b, c can be made of quaternary InGaAsP, for example. The transition layers 107a, b, c can transition from a first transition layer 107a in contact with the absorption layer 105 and having a higher concentration of GaAs, to a last transition layer 107c having a higher concentration of P, for example. Any suitable number of transition layers 107a, b, c (e.g., three as shown) is contemplated herein. Any suitable transition gradient to allow proper bonding/growth lattice mismatch and band discontinuity transition of layers between the absorption layer 105 and a charge control layer 109 (e.g., as disclosed below) is contemplated herein. One or more (e.g., all) of the transition layers 107a, b, c can be undoped or lightly doped the same type as the substrate 101 (e.g., n-doped or p-doped), for example.

The structure 100 can include a charge control layer 109 disposed on the last transition layer 107c. The charge control layer 109 can be doped the same type as the substrate layer 101 (e.g., n-doped as shown). In certain embodiments, the charge control layer 105 can be made of n-doped InP, for example. The thickness of the charge control layer 109 can be sized so that the gain is not too low, but also so that concentration is not too low. One having ordinary skill in the art in view of this disclosure can determine the proper relative sizing and concentration of the charge control layer 109 to provide desired gain, for example.

The structure 100 can include a charge layer 111 disposed on the charge control layer 109. The charge layer 111 can be undoped or lightly doped the same type as the substrate layer 101 (e.g., n-doped as shown). The charge layer 111 can be made of undoped InP, for example. The charge layer 111 can be relatively thick (e.g., about 3-1 to about 5 microns in certain embodiments).

The structure 100 can include a cap layer 113 disposed on the charge layer. The cap layer 113 can be undoped or mildly doped the same type as the substrate layer 101. In certain embodiments, the cap layer 113 can be made of an n-doped InP. The cap layer 113 can be lightly n-doped for having a better interface with a dielectric (e.g., 125 which can be made of SiN).

The structure 100 can include a detector active area 115 disposed within the charge layer 111 and the cap layer 113. The detector active area 115 can be doped the opposite type as the substrate 101. For example, the detector active area 115 can be or include a strongly doped material (e.g., p-doped as shown, made of zinc, silicon, or other suitable material). The detector active area 115 can extend through the cap layer 113 and into the charge layer 111 to a depth (e.g., as shown) thereby defining a multiplication region 117 of the charge layer 111 between the detector active area 115 and the charge control layer 109. The multiplication region 117 is the distance between detector active area 115 i.e junction in the charge layer 111 and charge control layer 109. The multiplication region 117 can be between about 0.12 and about 0.13 micron in certain embodiments. In certain embodiments, the multiplication region 117 can be as small as 0.05 micrometers to as large as 0.2 micrometers, depending on the speed and gain for example.

The detector active area 115 can include a shape, e.g., rounded as shown, without any sharp edges within the charge layer 111 and the cap layer 113 to prevent electric field concentration. For example, in certain embodiments, the detector active area 115 can have a semi ellipsoidal shape. The detector active area 115 can be or include a hemispherical shape, for example (e.g., as shown). While the embodiments shown includes a that is contemplated herein (e.g., a semi-ellipsoidal shape, or any other smooth shape), e.g., designed to prevent electric field concentration and/or to control a location and depth of the multiplication region 117. For example, as shown, the detector active area 115 can have a cross-sectional profile that is semi-circular or any other suitable smooth curve (e.g., a single uniform curve, multiple curves, etc.) without having concentrated electric field along the perimeter of the detector active area. Any shape is contemplated herein where there is no concentrated electric field around the perimeter of the detector active area.

In certain embodiments, the detector active area 115 can have a flat top surface that is flush with a top of the cap layer 113, e.g., as shown. The detector active area 115 can be centered relative to the layers 111, 113, or in any other suitable position.

The detector active area 115 can be diffused, epitaxially grown, and/or etched. Any suitable method to form the detector active area 115 is contemplated herein.

The structure 100 can also include an anode 119 disposed on the detector active area 115. The anode 119 can be made of any suitable conductive material (e.g., a metal). The anode 119 can include any suitable shape (e.g., a T-shaped cross-section as shown).

The structure 100 can also include a cathode 121 having an optical opening 121a. The cathode 121 can be disposed on the substrate layer 101 on an opposite side thereof as the buffer layer 103. The cathode 121 can be made of any suitable material (e.g., metal)

The structure 100 can also include a cathode dielectric 123 disposed in the optical opening 121a. The structure 100 can also include an anode dielectric 125 disposed between the anode 119 and the cap layer 113, for example. The anode dielectric 125 can extend over a portion of the detector active area 115, for example (e.g., as shown). The dielectrics 123, 125 can any suitable dielectric material, e.g., SiN.

In certain embodiments, all layers can be doped the same type (e.g., n-type or p-type) as the substrate 101, except the detector active area 115 will be opposite

Each layer 101-113 can include a relative thickness, e.g., as shown in FIG. 1. The thickness of each layer can be optimized to provide desired operational characteristics. The structure 100 can be scaled to any suitable size, e.g., between about 1 micron and 1 mm. The structure 100 can form a pixel, for example or a pixel surrounded by a ring of diffusion to limit the electric field.

In certain embodiments, the photodiode structure 100 forms an avalanche photodiode. Any other photodiode type and any suitable operating wavelengths thereof are contemplated herein. Referring additionally to FIG. 2, the structure 100 can be configured to function at one or more wavelengths between about 1000 nm to about 1700 nm wavelengths. Certain embodiments can also be extended to between about 400 nm to about 2600 nm wavelengths using the InₓGa₁₋ₓAs absorption layer with a sub 70V breakdown voltage (e.g., a breakdown voltage between 35V and 45V). Thus, embodiments of structures (e.g., structure 100) as disclosed herein can have sensitivity for, e.g., about 1500 nm wavelengths or from 400 nm to 2600 nm wavelengths, for example, and have low dark current (e.g., several orders of magnitude below the light current).

In certain embodiments, changing the InGaAs proportions of layer 105, can achieve the about 400 nm to about 2600 nm range or changing the InGaAs to InₓGa₁₋ₓAsᵥP_{1-y} layer with bandgap tuned to the desired operating wavelength between 400 nm to 2600 nm, however other layers may require change to address the lattice mismatch between adjacent layers, for example. As an example, referring to FIG. 1A, all InP layers can be changed to InAsP of suitable compositions, except the substrate 101 (which can remain InP). In certain embodiments, layer 103 can be broken up into a plurality of transition layers transitioning from a higher concentration of InP from the substrate 101, to a higher InAs concentration to layer 105.

In certain embodiments, as shown in FIG. 1B, a range of about 400 nm to about 1000 nm can be achieved without changing material as compared to FIG. 1, however, an etched substrate 101 in the area of the vertical projection of the active area 115 may be utilized as shown where surface 123 is located. Embodiments can enable NIR-SWIR, VIZ-SWIR, and extended SWIR, for example.

FIG. 1 shows a back-illuminated planar InP/InGaAs/InGaAsP avalanche photodiode structure. The multiplication region 117 can be an undoped InP charge layer 111 coupled with a charge control layer 109 composed of an n-type region. These coupled layers can provide a high and uniform electric field in the multiplication region. The separated electric field in the multiplication region 117 and absorption layers 105 can effectively reduce the band-to-band tunneling and enables the operation of avalanche photodiode at higher gain voltages. This high electric field can cause an increase in the impact ionization collision rate of both electrons and holes. High electric filed in the multiplication region can reduce the carrier path length, transit time and avalanche buildup time. The function of the InP charge control layer can be to maintain a high electric field for the multiplication region to achieve multiplication (gain) through impact ionization of carriers and low electric field for the absorption region to prevent high-field induced tunneling current. The thickness and carrier concentration of the charge control layer 109 can be optimized keeping the total charge density to be constant to achieve high performance. The thickness of the charge control layer can vary from 50 nm to 1500 nm to achieve the charge density of 2-4E12/cm⁻². The absorption layer 105 thickness can be further optimized to balance the quantum efficiency and the frequency response. The thickness of the absorption layer can vary from 0.9 to 1.5 μm to achieve>90% quantum efficiency. To reduce avalanche build up time and hence faster operation, the thickness of the multiplication region 117 can be optimized. The multiplication region thickness can vary from 0.05 um to 0.5 um.

In accordance with at least one aspect of this disclosure, a photodetector (not shown, e.g., a short wave infrared (SWIR) camera) can include a plurality of pixels. Each pixel can be and/or include a photodiode structure 100 as disclosed herein, e.g., as described above. In certain embodiments, the photodetector can be configured to sense one or more wavelengths between about 1000 nm to about 1700 nm, or between about 400 nm and about 2600 nm, for example.

In accordance with at least one aspect of this disclosure, a photodiode structure (e.g., structure 100) can include a charge layer (e.g., layer 111) comprised of undoped InP, and a detector active area (e.g., 115) forming a p+ junction with the charge layer and having round edges configured to prevent edge breakdown. The location of the p+ junction can be controlled through a diffusion of the detector active area (e.g., 115), for example. The photodiode structure can also include a charge control layer (e.g., 109) comprised of n-doped InP. The charge control layer can include a thickness and carrier concentration configured to achieve a predetermined gain, high speed, low dark current, and low break down voltage (e.g., about 40V).

A method can include forming a smooth detector active area to form a strongly p-doped (p+) junction for a photodiode. Forming the smooth detector active area can include diffusing the detector active area into smooth cavity within a charge layer (e.g., 111) and/or a cap layer (e.g., 113) such that the detector active area has no sharp edges. The detector active area can be formed in a photodetector structure that is configured to sense one or more wavelengths between about 1000 nm to about 1700 nm, and/or one or more wavelengths between about 400 nm to about 2600 nm. Any other suitable method is contemplated herein.

Embodiments can include low and uniform breakdown voltage planar InGaAs/InP SACM near infrared avalanche photodetector focal plane arrays. Embodiments can include InP/InGaAsP/InGaAs/InP based separate absorption charge and multiplication (SACM) device with a thin InP cap layer and charge layer by adjusting the charge control layer to have sufficient electric field to achieve the multiplication but not reach the tunneling field. The charge layer thickness can be varied from 1.0 um to 3 um depending on the placement control capability of the p+ diffusion in the charge layer. The charge control layer subsequently manages the electric field and if the charge layer is made too thin then the electric field could potentially drift into the InGaAs absorption layer causing the spurious tunneling current and ultimately unwanted breakdown.

Embodiments provide a reduction in break down voltage and reduce the need for higher supply voltages in a system and reduces the power dissipation of the overall system. In addition, the reduction in the break down voltage lowers the operating voltage in the linear mode thus reducing the dark current. Reduction in dark current significantly improves the S/N ratio of cameras using such pixel structures (e.g., for short wave infrared (SWIR) cameras), for example. The lower break down voltage can also lead to higher margin of electric field below the break down and can reduce the signal non-uniformity in a large format focal plane array.

Embodiments allow for the design and fabrication of an avalanche photodiodes (APD) to achieve low and uniform breakdown voltage across a large format APD pixel arrays operating at 1000 to 1700 nm wavelengths operating at or near room temperature. Embodiments can include varying the thickness of the InP charge layer depending the control of the position of the p+ diffusion and the width of the multiplication region, formation of a p+ junction with edges that prevent the edge breakdown, precise control through a controlled diffusion process either through metal organic chemical vapor deposition chamber or through a closed ampule thermal evaporation process or through some other diffusion process or through ion-implantation to achieve the desired location of the p+ junction through diffusion process, and selecting the thickness and carrier concentration of the charge control layer to achieve sufficient gain, high speed and low dark current and low break down voltage. The thickness and carrier concentration of the charge control layer are designed to achieve the desired charge density between 2-5E12 cm⁻². A thicker charge control region prevents premature breakdown, but has the adverse effect of exhibiting significant avalanche build up time which lowers the speed of the carriers drifting to the anode. The charge density will also define the breakdown voltage. The charge density must be optimized such that a low breakdown voltage is achieved with high gain as well.

While certain compositions have been disclosed above, any other suitable compositions and/or combinations thereof that perform equivalently or suitably similar are contemplated herein. Any suitable compositions are contemplated herein.

Those having ordinary skill in the art understand that any numerical values disclosed herein can be exact values or can be values within a range. Further, any terms of approximation (e.g., “about”, “approximately”, “around”) used in this disclosure can mean the stated value within a range. For example, in certain embodiments, the range can be within (plus or minus) 20%, or within 10%, or within 5%, or within 2%, or within any other suitable percentage or number as appreciated by those having ordinary skill in the art (e.g., for known tolerance limits or error ranges).

The articles “a”, “an”, and “the” as used herein and in the appended claims are used herein to refer to one or to more than one (i.e., to at least one) of the grammatical object of the article unless the context clearly indicates otherwise. By way of example, “an element” means one element or more than one element.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

Any suitable combination(s) of any disclosed embodiments and/or any suitable portion(s) thereof are contemplated herein as appreciated by those having ordinary skill in the art in view of this disclosure.

The embodiments of the present disclosure, as described above and shown in the drawings, provide for improvement in the art to which they pertain. While the subject disclosure includes reference to certain embodiments, those skilled in the art will readily appreciate that changes and/or modifications may be made thereto without departing from the spirit and scope of the subject disclosure.

What is claimed is:

1. A photodiode structure, comprising:
a substrate layer comprising strongly doped InP;
a buffer layer disposed on the substrate layer and comprising InP, wherein the buffer layer is either undoped or doped the same type as the substrate;
an absorption layer disposed on the buffer layer and comprising InGaAs, wherein the absorption layer is undoped mildly doped the same type as the buffer layer;
a plurality of transition layers disposed on the absorption layer, the plurality of transition layers comprising quaternary InGaAsP and transitioning from a first transition layer in contact with the absorption layer having a higher concentration of GaAs to a last transition layer having a higher concentration of P;
a charge control layer disposed on the last transition layer and comprising doped InP, wherein the charge control layer is doped the same type as the substrate layer;
a charge layer disposed on the charge control layer and comprised of InP, wherein the charge layer is undoped or lightly doped the same type as the substrate layer;
a cap layer disposed on the charge layer and comprised of InP, wherein the cap layer can be undoped or mildly doped the same type as the substrate layer;
a detector active area disposed within the charge layer and the cap layer, the detector active area comprising a strongly doped material, wherein the detector active area is doped the opposite type as the substrate, the detector active area extending through the cap layer and into the charge layer to a depth thereby defining a multiplication region of the charge layer between the detector active area and the charge control layer, wherein the detector active area includes a shape that does not have any sharp edges within the charge layer and the cap layer to prevent electric field concentration;
an anode disposed on the detector active area; and
a cathode having an optical opening, the cathode disposed on the substrate layer on an opposite side thereof as the buffer layer.

2. The structure of claim 1, further comprising a cathode dielectric disposed in the optical opening.

3. The structure of claim 2, further comprising an anode dielectric disposed between the anode and the cap layer.

4. The structure of claim 3, wherein the anode dielectric extends over a portion of the detector active area.

5. The structure of claim 1, wherein each layer includes a relative thickness as shown in FIG. 1.

6. The structure of claim 1, wherein the detector active area has a semi ellipsoidal shape.

7. The structure of claim 6, wherein the detector active area is a hemispherical shape.

8. The structure of claim 7, wherein the photodiode structure forms an avalanche photodiode.

9. An avalanche photodetector comprising:
a plurality of pixels, each pixel comprising:
a photodiode structure as recited in claim 1.

10. The avalanche photodetector of claim 9, wherein the photodetector is configured to sense one or more wavelengths between about 1000 nm to about 1700 nm, and/or one or more wavelengths between about 400 nm to about 2600 nm.

11. The avalanche photodetector of claim 9, further comprising a cathode dielectric disposed in the optical opening.

12. The avalanche photodetector of claim 11, further comprising an anode dielectric disposed between the anode and the cap layer.

13. The avalanche photodetector of claim 12, wherein the anode dielectric extends over a portion of the detector active area.

14. The avalanche photodetector of claim 9, wherein each layer includes a relative thickness as shown in FIG. 1.

15. The avalanche photodetector of claim 9, wherein the detector active area has a semi ellipsoidal shape.

16. The avalanche photodetector of claim 15, wherein the detector active area is a hemispherical shape.

17. The avalanche photodetector of claim 9, wherein the photodiode structure forms an avalanche photodiode.

18. An avalanche photodiode structure, comprising:
a charge layer comprised of undoped InP;
a detector active area forming a junction with the charge layer and having edges configured to prevent edge breakdown, wherein the location of the junction is controlled through a diffusion of the detector active area or through an epitaxially grown doped region; and
a charge control layer comprised of doped InP, wherein the charge control layer includes a thickness and carrier concentration configured to achieve a predetermined gain, high speed, low dark current, and low break down voltage.

19. A method, comprising:
forming a smooth detector active area to form a strongly doped junction for a photodiode.

20. The method of claim 19, wherein the detector active area is formed in a photodetector structure that is configured to sense one or more wavelengths between about 1000 nm to about 1700 nm, and/or one or more wavelengths between about 400 nm to about 2600 nm.
